(19) United States
(12) Patent Application Publication
(10) Pub. No.: US 2024/0052482 A1
(43) Pub. Date: Feb. 15, 2024

(54) COATING SYSTEM FOR PLASTIC PROCESSING APPLICATIONS

(71) Applicant: OERLIKON SURFACE SOLUTIONS AG, PFÄFFIKON, Pfäffikon (CH)

(72) Inventor: Anders OIof ERIKSSON, Chur (CH)

(73) Assignee: OERLIKON SURFACE SOLUTIONS AG, PFÄFFIKON, Pfäffikon (CH)

(21) Appl. No.: 18/278,443

(22) PCT Filed: Feb. 23, 2022
(86) PCT No.: PCT/EP2022/054519

§ 371 Date: Aug. 23, 2023

(30) Foreign Application Priority Data
Feb. 23, 2021 (DE) 10 2021 000 958.4

(51) Int. Cl. C23C 16/30; C23C 16/52

(52) U.S. Cl. CPC C23C 16/303; C23C 16/52

(57) ABSTRACT

A multilayer coating exhibits good corrosion resistance and good abrasion resistance. The multilayer coating includes layers A and layers B deposited forming a sequence of the type . . . A/B/A/B/A . . . , with the layers A being CrN-based layers or CrN layers and the layers B being CrON-based layers or CrON layers. The multilayer coating exhibits a modulated ratio of the thicknesses of the A layers and B layers, in a manner that the multilayer coating comprises at least two different coating portions along the whole multilayer coating thickness, with differently adjusted ratio of the thicknesses of the A layers and B layers.

Plastic processing applications like injection molding or extrusion contains various stages where metal tools come in a physical contact with plastic. This causes the tool, e.g. injection molds, to suffer from a combined corrosive and abrasive attack. Corrosive media induced by plastics can be originated from e.g. softener, colors, and free hydrochloric acid used in plastics. At the same time, the increasing interest in use of glass fiber reinforced plastics in different plastic processing applications, e.g. injection molding produced parts for automotive industry, has led to more abrasive wear on tools. Glass fiber reinforced plastics with a glass fiber content of >30% are extremely abrasive and reduce the tool life.

For the purpose of extending the lifetime of tools used in plastic processing applications, PVD coatings combining abrasive wear resistance and corrosion resistance are required.

Bolvardi proposes in the document WO2020099605 a coating system to meet the requirements of plastic processing applications, the coating system comprising:
an under layer comprising at least one corrosion resistant material layer, preferably one or more AICrO layers as corrosion resistant layers,
an upper layer comprising one or more abrasion resistant material layers, preferably one or more CrON layers as abrasion resistant layers, and
a transition layer provided between the first layer and the second layer.

Bolvardi mentions furthermore in the document WO2020099605 that a multilayer coating of the type . . . CrN/CrON/CrN/CrON . . . only provides a good abrasion resistance but a poor corrosion resistance.

In despite of the advances attained by the prior art, the increased demand on further improvements for attaining the required tool performance during plastic processing applications in a sustainable manner makes necessary to work on further coating solutions for meeting these increased demands.

### OBJECTIVE OF THE PRESENT INVENTION

The objective of the present invention is to provide a coating system produced in a sustainable manner for attaining a good combination of corrosion resistance and abrasion resistance that can be suitable for enhancing performance of tools used in plastic processing applications.

A further objective of the present invention is to provide a forming tool having a surface to be exposed to contact with plastic during plastic processing applications, said surface being treated and/or coated previous to use (previous to be used in any plastic processing applications) in such a manner that it exhibits a suitable combination of good abrasion resistance and good corrosion resistance during the use.

### DESCRIPTION OF THE PRESENT INVENTION

The objective of the present invention is attained by providing a multilayer coating comprising a plurality of layers deposited one on each other, wherein:
individual chromium nitride based (CrN-based) layers or individual chromium nitride (CrN) layers, and
individual chromium oxynitride based (CrON-based) layers or individual chromium oxynitride (CrON) layers
are deposited one on each other forming a sequence of the type . . . CrN/CrON/CrN/CrON/CrN . . . , and wherein the ratio between the layer thicknesses of two layers deposited one on each other is modulated along the thickness of the multilayer coating.

For simplifying the description of the invention, the individual CrN-based layers or individual CrN layers will be referred as to A layers and the individual CrON-based layers or individual CrON layers will be referred as to B layers.

The wording “the ratio between the layer thicknesses of two layers deposited one on each other is modulated along the thickness of the multilayer coating” refers to a specific variation of the ratio between the layer thicknesses of two individual layers, i.e. one A layer and one B layer, when the one A layer is deposited on the one B layer.

Since the thickness of the individual layers (A layer or B layer) can lightly vary because light intrinsic variations in the coating conditions during coating deposition in despite of setting the same coating process parameters, then thickness of the individual layers (A layers or B layers) should be understood as an average layer thickness of the individual layers (A layers or B layers).

The inventor found that surprisingly with a multilayer coating of the type . . . A/B/A/B/A . . . , with layers A and layers B as defined above:
the corrosion resistance of the multilayer coating can be enhanced by adjusting the thickness of the A layers in relation to the thickness of the B layers in a way that the average thickness of the A layers is thicker in comparison with the average thickness of the B layers,
the abrasive wear resistance of the multilayer coating can similarly be improved but by adjusting the thickness of the A layers in relation to the thickness of the B layers in a way that the average thickness of the A layers is thinner in comparison with the average thickness of the B layers, and
both the abrasive wear resistance and the corrosion wear resistance of the multilayer coating can be improved by depositing the multilayer coating with modulated ratio of the thicknesses of the A layers and B layers, in a manner that the multilayer coating comprises at least two different coating portions along the whole multilayer coating thickness, with differently adjusted ratio of the thicknesses of the A layers and B layers, in particular the multilayer coating should comprise:
   an under multilayer coating portion in which the average thickness of the A layers is thicker than the average thickness of the B layers, and
   an upper multilayer coating portion in which the average thickness of the A layers is thinner than the average thickness of the B layers,
   wherein when the multilayer coating is deposited in a substrate surface, preferably the under multilayer coating portion is deposited closer to the substrate surface than the upper multilayer coating portion.

In the context of the present invention a CrN-based layer or CrN layer (also referred to as A layer in the context of the present invention) is a chromium nitride layer which might comprises other chemical elements as doping elements or alloying elements.

Such a layer can have for example an average chemical composition given by the following formula:

(CrₐX_{b})_{q}(N_{d}Zₑ)ᵣ

wherein a, b, d and e are the coefficients representing the percentage in atomic concentration of Cr, X, N and Z, respectively, q and r are the coefficients indicating the stoichiometry (rlq=1) or hyper-stoichiometry (rlq>1) or sub-stoichiometry (rlq<1), and wherein:
Cr is the chemical element chromium
N is the chemical element nitrogen
X is one or more chemical elements selected from: Ti, Zr, Hf, Sc, Y, V, Nb, Ta, In, Si, Ge, Sn, Al, Mo, W, Ni, Pd, Pt, Cu, Ag, Au, B,
Z is one or more chemical elements selected from: carbon (C) and oxygen (O), wherein if X is O or if X comprises O, then the concentration of O in atomic percentage in the sum of N+Z should not be higher than 5 in atomic percentage. It means concretely that for example, if X=0, then e can be maximal 5, i.e. if X=O, then 0≤e≤5
a+b=100, with 023 b≤20, preferably with 0≤b≤15, more preferably with 0≤b≤10 or 0≤b≤5
d+e=100, with 0≤e≤30, preferably with 0≤e≤20, more preferably with 0≤e≤10 or 0≤e≤5
0.90<r/q°≤1.10

In the context of the present invention a CrON layer is a chromium oxynitride layer which might comprises other chemical elements as doping elements or alloying elements. Such a layer can have for example an average chemical composition given by the following formula:

(Cr_{f}Dₜ)_{g}(OₕNⱼCₘ)ᵤ

wherein f, t, h, j and m are the coefficients representing the percentage in atomic concentration of Cr, D, O, N and Q, respectively, g and u are the coefficients indicating the stoichiometry (ulg=1) or hyper-stoichiometry (ulg>1) or sub-stoichiometry (ulg<1), and wherein:
Cr is the chemical element chromium
N is the chemical element nitrogen
D is one or more chemical elements selected from: Ti, Zr, Hf, Sc, Y, V, Nb, Ta, In, Si, Ge, Sn, Al, Mo, W, Ni, Pd, Pt, Cu, Ag, Au, B,
C is the chemical element carbon (C),
f+t=100, with 0≤t≤20, preferably with 0≤t≤15, more preferably with 0≤t≤10 or 0≤t≤5
h+j+m=100, with 5<j≤70, preferably with 5<j≤60, more preferably with 10≤j≤60 or 10<j<55, and with 0≤m≤15, preferably with 0≤e≤10.
0.90<r/q°<1.10

In other words, the average layer thicknesses ratio, LTR, is defined by the formula:

$$LTR = \frac{average A layer thickness}{average B layer thickness}$$

In order to explain the invention in more detail, following Figures will be used:

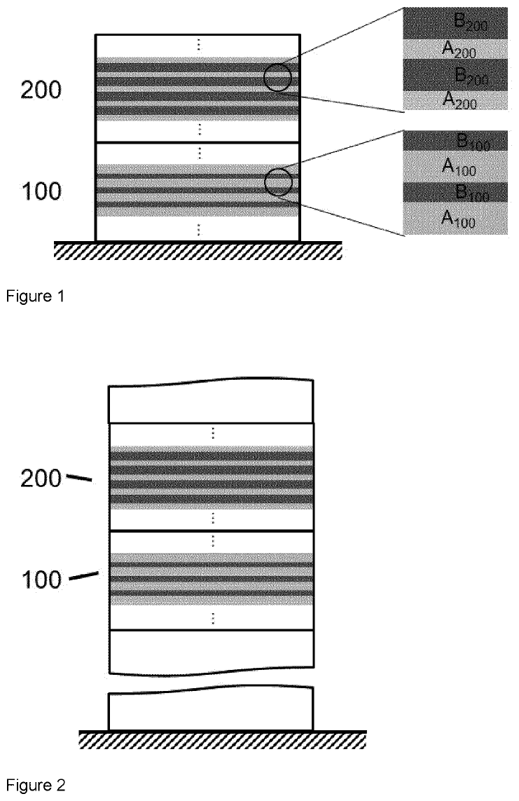

FIGS. 1 and 2 schematic representation of coating designs, including an under multilayer coating portion 100 and an upper multilayer coating portion 200—A layers in bright grey, B layers in dark grey.

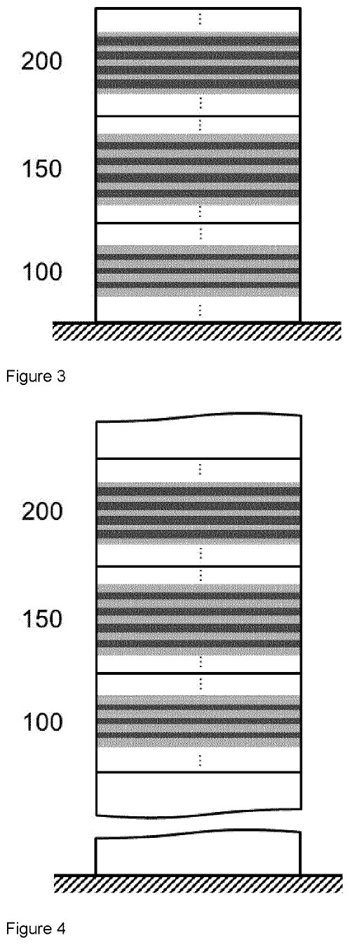

FIGS. 3 and 4 schematic representation of coating designs, including an under multilayer coating portion 100, and intermediate multilayer coating portion 150 and an upper multilayer coating portion 200—A layers in bright grey, B layers in dark grey.

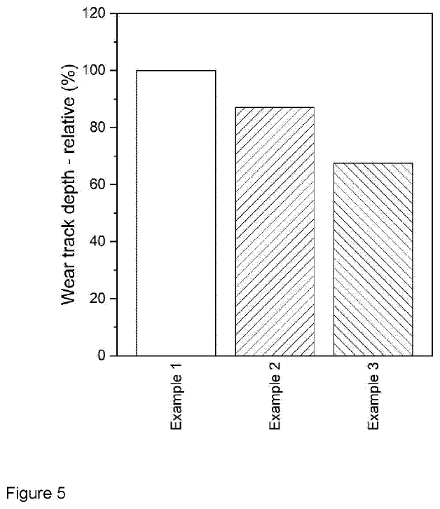

FIG. 5 Wear track depth after SRV measurement to evaluate abrasive wear resistance. Less abrasive wear corresponds to lower wear track depth, i.e. the lower height of the bar, the higher the abrasive wear resistance. The values are normalized relative to the results corresponding to Example. Examples 1 is an comparative example, Examples 2 and 3 are inventive examples.

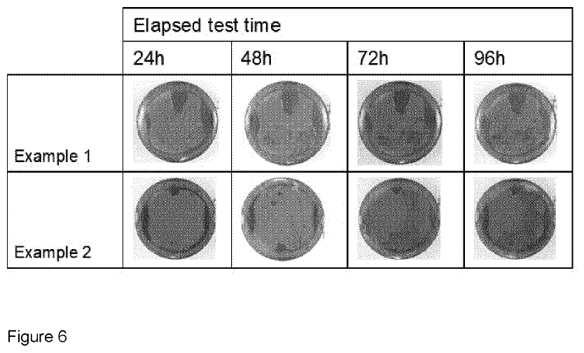

FIG. 6 Steel samples documented after different elapsed time in NSST test.

Hence, in an under multilayer coating portion 100, the average layer thickness ratio, LTR100, is given by considering the average layer thickness of the A layers in the under multilayer coating portion 100, i.e. the average layer thickness of the A100 layers, and the average layer thickness of the B layers in the under multilayer coating portion 100, i.e. average layer thickness of the B100 layers:

$$LTR 100 = \frac{average thickness of A 100}{average thickness of B 100}$$

And similarly, in an upper multilayer coating portion 200, the average layer thickness ratio, LTR200, is given by considering the average layer thickness of the A layers in the upper multilayer coating portion 200, i.e. the average layer thickness of the A200 layers, and the average layer thickness of the B layers in the upper multilayer coating portion 200, i.e. average layer thickness of the B200 layers:

$$LTR 200 = \frac{average thickness of A 200}{average thickness of B 200}$$

The inventor observed an important improvement in the combination of corrosion resistance and abrasion resistance, when a multilayer coating with at least two multilayer coating portions was produced, in a manner that the average layer thickness ratio LTR100 in the under multilayer coating portion 100 was greater than the average layer thickness ratio LTR200 in the upper multilayer coating portion 200, i.e. when LTR100>LTR200.

In particular, a surprisingly good combination of high corrosion resistance and high abrasion resistance was obtained in a preferred embodiment of the present invention, in which the multilayer coating was produced with at least two multilayer coating portions, an under multilayer coating portion 100 having average layer thickness ratio LTR100>1 and an upper multilayer coating portion 200 having average layer thickness ratio LTR200<1.

A multilayer coating according to the present invention can also comprise further coating portions or further coating layers.

According to a further preferred embodiment of the present invention the multilayer coating comprises an intermediate multilayer coating portion 150 deposited between the under multilayer coating portion 100 and the upper multilayer coating portion 200.

The intermediate multilayer coating portion 150, having an average layer thickness ratio, LTR150, given by considering the average layer thickness of the A layers in the intermediate multilayer coating portion 150, i.e. the average layer thickness of the A150 layers, and the average layer thickness of the B layers in the intermediate multilayer coating portion 150, i.e. average layer thickness of the B150 layers:

$$LTR 150 = \frac{average thickness of A 150}{average thickness of B 150}$$

wherein LTR100>LTR150>LTR200 According to one more further preferred embodiment, the multilayer coating comprises more than three multilayer coating portions, wherein the first multilayer coating portion is the under multilayer coating portion 100 and the last multilayer coating portion is the upper multilayer coating portion 200, wherein each multilayer coating portion has a different average layer thickness ratio LTR and the LTR decreases gradually (continuously or stepwise) from the under multilayer coating portion up to the upper multilayer coating portion.

Preferably, the layers of CrN within one coating portion have approximately the same coating thickness, and preferably the layers of CrON within one coating portion have approximately the same coating thickness. Variations can occur for instance though due to substrate rotation and relative orientation of the deposition sources in the PVD deposition system.

Preferably the thickness of one bilayer, i.e. the thickness of the sum of one B layer plus one A layer deposited one on the other is in a range of 30 nm to 500 nm, more preferably in a range of 100 nm to 200 nm, for example the bilayer thickness can be 150 nm.

The total multilayer coating thickness is preferably between 1 μm and 30 μm, more preferably between 2 μm and 20 μm, still more preferably between 5 and 10 μm.

The thickness of one multilayer coating portion, e.g. the thickness of the under multilayer coating portion 100 or the thickness of the upper multilayer coating portion 200 is preferably not lower than 10% of the total multilayer coating thickness.

Preferably, the coating comprise a cubic fcc-CrN phase. This can for example be characterized by X-ray diffraction.

The coating has preferably an indentation hardness larger than 20 GPa, in particular in the range 25-35 GPa.

The coating according to the present invention can also comprise a bottom coating layer, which is deposited between the substrate surface on which the multilayer coating is deposited and the under multilayer coating portion.

The bottom coating layer can be for example be deposited directly on the substrate surface for improving adhesion of the coating to the substrate surface. In this case, the bottom coating layer can be for example a CrN layer or a Cr layer or can be a layer comprising any of CrN or Cr.

The coating according to the present invention can also comprise a top coating layer, which is deposited atop the coating, above the upper multilayer coating portion.

The top coating layer can be for example be deposited as outermost layer directly on the upper multilayer coating portion for improving any further surface properties.

The top coating layer can be for example a CrON layer for reducing tendency to stick to plastic materials.

Application of the described coatings can be combined with nitriding pre-treatment. This can be done either in a separate vacuum or atmospheric nitriding process, or in-situ prior to application of the first surface layer.

The inventive coatings can be deposited by using known PVD techniques.

The use of a negative bias voltage applied to the substrate during deposition of the multilayer coating portions was found to be advantageous, for example a negative bias voltage between 10 V and 150 V (in absolute value).

Inventive examples and comparative examples:

The present description including Figures and examples are not provided with the intention to limit the invention but only to help to understand the invention. Therefore, the examples given in the present description should not be understood as a limitation of the invention.

For the deposition of the inventive coatings as well as for the deposition of the comparative coatings described in the examples below, an Oerlikon Balzers INNOVENTA mega PVD deposition system was used.

The examples of inventive coatings as presented below were deposited through arc deposition from Cr-targets. The multilayer architecture was obtained through alternating pure N2 atmosphere for deposition of CrN, and an atmosphere of a mixture between N2 and O2. Several sequences of pure N2 atmosphere, followed by mixed N2/O2 atmosphere were repeated to obtain coatings with a sequence of several bilayer periods consisting of CrN and CrON individual layers.

The thickness ratio between CrN and CrON layers was modulated (i.e. controlled) by adjusting the time duration of the deposition sequence in pure N2 atmosphere and the time in mixed N2/O2 atmosphere.

In the FIGS. 5 and 6 are shown the results regarding corrosion resistance test and abrasion resistance test conducted in substrates coated with a comparative example according to Example 1 and two comparative examples according to Example 2 and Example 3.

### Comparative Examples 1:

A multilayer coating comprising CrN layers and CrON layers with average layer thickness ratio LTR=1, i.e. with average layer thickness of the individual CrN layers in the same magnitude (same average thickness layer value) as the individual CrON layers was deposited and tested. For some of the tests, in particular for the tests shown in FIGS. 5 and 6 a bottom layer of CrN was deposited between the substrate surface and the multilayer coating.

### Inventive Examples 2:

Different inventive multilayer coatings comprising A layers of the type CrN layers and B layers of the type CrON layers, the multilayer coatings formed by two different multilayer coating portions, an under multilayer coating portion having LTR between 2 and 1.3 and an upper multilayer coating portion with LTR between 0.8 and 0.3 were deposited and tested. For some of the tests, in particular for the tests shown in FIGS. 5 and 6 a bottom layer of CrN was deposited between the substrate surface and the multilayer coating. For the tests shown in FIGS. 5 and 6, LTR in the under multilayer coating portion was between 1.55 and 1.75, and LTR in the upper multilayer coating portion was between 0.4 and 0.7.

### Inventive Examples 3:

The only difference between Example 2 and 3 was that the multilayer coatings were deposited with an additional multilayer coating portion, more exactly an intermediate multilayer coating portion with LTR between 1.2 and 0.9. For the tests shown in FIGS. 5 and 6, LTR in the intermediate multilayer coating portion was about 1.

Description of the tests:

Abrasive wear resistance of the coatings was investigated using sliding reciprocal wear (SRV) measurements. A ball made of Al2O3was used in reciprocal sliding motion, with 10 Hz under constant applied force (50 N) and for 60 min. The depth of the resulting wear track was measured and is presented in FIG. 5. A low wear track depth correspond to high abrasive wear resistance. As can be seen in FIG. 5, the inventive coatings (see Examples 2 and 3 in FIG. 5) display higher abrasive wear resistance than the comparative coating (see Example 1 in FIG. 5) produced according to the prior-art.

In order to evaluate the corrosion resistance of the coatings, the inventive coatings and the comparative coatings produced according to the prior-art were tested using a neutral salt spray test (NSST). The coatings were applied to a substrate made of 1.2842 cold work steel with 0.4 at % Cr. As exemplified in FIG. 6, the comparative coating (see Example 1 in FIG. 6) shows pitting corrosion on a main part of the surface after 72-96 hours. With the inventive coating (see Example 2 in FIG. 6), good corrosion resistance was attained.

These two tests confirm that the inventive coatings combine good corrosion resistance and high abrasive wear resistance.

1-6. (canceled)

7. A multilayer coating with layers A and layers B deposited forming a sequence of the type . . . A/B/A/B/A . . . , the layers A being CrN-based layers or CrN layers and the layers B being CrON-based layers or CrON layers, wherein the multilayer coating exhibits a modulated ratio of the thicknesses of the A layers and B layers, in a manner that the multilayer coating comprises at least two different coating portions along the whole multilayer coating thickness, with differently adjusted ratio of the thicknesses of the A layers and B layers, wherein:
the multilayer coating comprises:
an under multilayer coating portion with an average thickness ratio LTR100 of the average thickness of the A layers regarding the average thickness of the B layers, and an upper multilayer coating portion with an average thickness ratio LTR200 of the average thickness of the A layers regarding the average thickness of the B layers, wherein LTR100>LTR200.

8. The multilayer coating according to claim 7, wherein the multilayer coating is deposited in a substrate surface in such a manner that the under multilayer coating portion is deposited closer to the substrate surface than the upper multilayer coating portion.

9. The multilayer coating according to claims 8, wherein:
the under multilayer coating portion has average layer thickness ratio between the A layers and B layers, LTR100, greater than 1, i.e. LTR100>1, and the upper multilayer coating portion having average layer thickness ratio between the A layers and B layers, LTR200, LTR200<1.

10. The multilayer coating according to claim 7, wherein the multilayer coating comprises further coating portions or further coating layers.

11. The multilayer coating according to claim 10, wherein the multilayer coating comprises an intermediate multilayer coating portion deposited between the under multilayer coating portion and the upper multilayer coating portion.

12. The multilayer coating according to claim 11, wherein the intermediate multilayer coating portion has an average layer thickness ratio between the A layers and B layers, LTR150, wherein LTR100>LTR150 >LTR200.
